(19) United States
(12) Patent Application Publication
(10) Pub. No.: US 2006/0141744 A1
(43) Pub. Date: Jun. 29, 2006

(54) System and method of forming a bonded substrate and a bonded substrate product

(75) Inventors: Keith Frank Best, Prunedale, CA (US); Joseph J. Consolini, Costa Mesa, CA (US)

Correspondence Address: PILLSBURY WINTHROP SHAW PITTMAN, LLP, P.O. BOX 10500, MCLEAN, VA, 22102, US

(73) Assignee: ASML NETHERLANDS B.V., Veldhoven (NL)

(21) Appl. No.: 11/020,558

(22) Filed: Dec. 27, 2004

(51) Int. Cl. H01L 21/30; H01L 21/46

(52) U.S. Cl. 438/455

(57) ABSTRACT

The invention provides a method of forming a bonded substrate that includes providing a first substrate having a first substrate shape and at least one first alignment mark positioned at a first surface side. A second substrate is providing having a second substrate shape. The second substrate is oriented relative to the first substrate in a predetermined orientation. The second substrate is bonded to the first surface side of the first substrate to render the bonded substrate, such that the bonded second substrate does not cover the at least one first alignment mark.

### FIELD OF THE INVENTION

The present invention relates to a system and method of forming a bonded substrate and to a bonded substrate product.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g. comprising part of, one or several dies) on a substrate (e.g. a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at once, and so-called scanners, in which each target portion is irradiated by scanning the pattern through a radiation beam in a given direction (the “scanning”-direction) while synchronously scanning the substrate parallel or anti-parallel to this direction. It is also possible to transfer the pattern from the patterning device to the substrate by imprinting the pattern onto the substrate.

Wafer bonding is a technology used in micro-electronics fabrication, in which a first substrate carrying first devices on its surface is brought into contact with second devices on a surface of a second substrate for fabricating an electronic circuit. Typically, the contact is arranged in such a way that electronic signals can be transported from at least one first device on the first substrate to at least one second device on the second substrate and vice versa. The reason for using wafer bonding is cost savings during production and/or packaging and also an overall tendency of product shrinkage.

An example where wafer bonding is useful in reducing costs is when Si-based first devices are combined with second devices based on another substrate material such as a Ill-V or II-VI semiconductor substrate. Manufacturing both types of devices on a single substrate may be virtually impossible due to the incompatibility of the constituent materials.

Another example is an electronic circuit made from a first and second substrate in which electronic circuit devices, due to their complexity, need to be fabricated on separate wafers, even though both substrates may be based on a similar substrate type.

In cases where an electronic circuit or “chip” needs to combine two or more devices that are not manufactured on a single substrate, wafer bonding may provide a way to combine these devices into a single package with a desired (electronic) function.

There are several approaches for forming an electronic circuit made from a first and a second substrate. In one approach, devices are manufactured on the separate substrates, and consecutively the substrates are bonded. On each device an area is reserved for providing one or more contact pads (or bond pads). Such a contact pad is intended for providing a connection between one of the devices and a similar contact pad on the other of the devices. Typically, the location of (a) bond pad(s) within the device area is defined during the design of the device or the electronic circuit of which the device is a part. Disadvantage of this approach is that the bond pads on the devices to be bonded must have a sufficient alignment and overlap (i.e., a coincidence in their respective lateral positions within the device area) such that the electronic circuit formed from the devices is actually functional. However, since the bonding operation has a limited accuracy of about a few microns, the contacts of both devices in the first substrate and devices in the second substrate should be relatively oversized in comparison to the contact sizes that can be obtained by lithographic processing (typically 0.25 μm).

In order to bypass the lack of accuracy of the bonding operation, an alternative approach to form an electronic circuit made from a first and a second substrate may be used. In this approach, a first substrate may be provided with a device pattern forming one or more devices. The first substrate may be bonded to a second substrate, which does not comprise a device pattern yet. Consecutively, the second substrate in the bonded structure may be patterned, e.g. by exposing a target portion of the second substrate with a lithographic apparatus.

In order to position the device pattern in the second substrate accurately with respect to the position of device(s) in the device pattern of the first substrate the position of the latter should be known. A technique that is currently employed to acquire this position uses so-called etching windows. Before bonding, the first substrate is provided with one or more marks. After bonding, the marks are not visible anymore, since they are located at the bonded substrate interface. The location of the marks is then determined by employing infrared radiation after which an etching window, such as an aperture in an additional removable layer that is deposited on top of the surface of the second substrate, is formed at the determined location of the one or more marks of the first substrate at the bonded substrate interface. Consecutively, the second substrate may be etched at the positions of the windows until the marks of the first substrate at the substrate bonded interface are exposed. Finally, after removal of the layer provided with the etching windows, the surface of the second substrate to be exposed, can be aligned to the device pattern in the first substrate by using the exposed marks of the first substrate at the bonded substrate interface with a known alignment technique, for instance the technique disclosed by EP-patent application EP1336899.

This alignment technique has its limitations. The placement of the etching windows, as well as the time, which is needed to do the actual etching, may make the technique expensive when the thickness of the second substrate exceeds 100 μm. However, in integrated-circuit (IC) applications, a number of applications require so-called full thickness wafers, substrates with a thickness of about 650 μm.

### SUMMARY

It is desirable to provide a technique that enables the alignment of a second substrate having a thickness exceeding 100 μm and being bonded on top of a preferably patterned first substrate, that may be performed within limited time and at reduced costs. The invention provides a method of forming a bonded substrate including providing a first substrate having a first substrate shape and at least one first alignment mark that is positioned on a first surface side, providing a second substrate having a second substrate shape, orienting the second substrate relative to the first substrate in a predetermined orientation, and bonding the second substrate to the first surface side of the first substrate to render the bonded substrate such that the bonded second substrate does not cover the at least one first alignment mark. In the bonding process, the second substrate form should remain substantially unchanged.

The invention further relates to a bonded substrate including a first substrate with a first outer circumference and with at least one first alignment mark at a first surface side, and a second substrate that is placed on top of the first substrate with a second outer circumference, wherein the second outer circumference is at least partly enclosed by the first outer circumference such that the at least one first alignment mark is uncovered.

The invention further relates to a device manufacturing method including providing a substrate, providing a projection beam of radiation using an illumination system, using patterning means to impart the projection beam with a pattern in its cross-section, and projecting the patterning beam of radiation onto a target portion of the bonded substrate, wherein the substrate is a bonded substrate.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a lithographic apparatus according to an embodiment of the invention;

FIGS. 2a-c schematically show a cross-section of two different bonded structures that can be aligned in accordance with known alignment techniques;

FIGS. 3a-d schematically show a first embodiment of the present invention;

FIGS. 4a-c schematically show a second embodiment of the present invention;

FIGS. 5a-d schematically show a third embodiment of the present invention,

### DETAILED DESCRIPTION

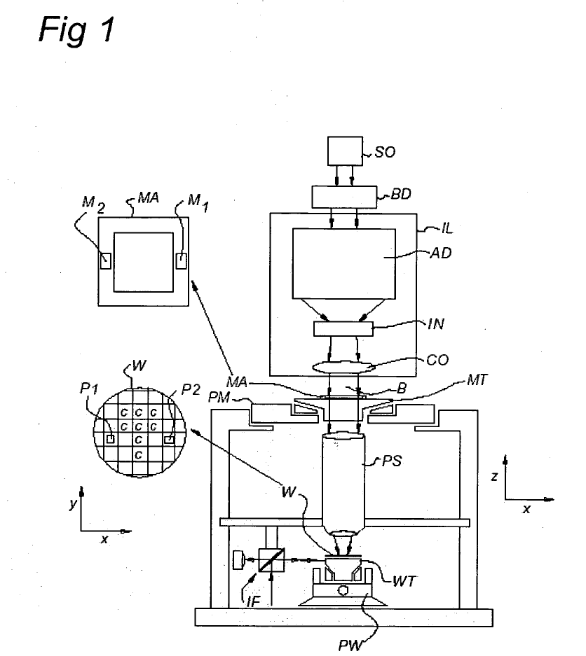

FIG. 1 schematically depicts a lithographic apparatus according to one embodiment of the invention. The apparatus includes:

an illumination system (illuminator) IL configured to condition a radiation beam B (UV radiation or EUV radiation or other radiation beam);

a support structure (e.g. a mask table) MT constructed to support a patterning device (e.g. a mask) MA and connected to a first positioner PM configured to accurately position the patterning device in accordance with certain parameters;

a substrate table (e.g. a wafer table) WT constructed to hold a substrate (e.g. a resist-coated wafer) W and connected to a second positioner PW configured to accurately position the substrate in accordance with certain parameters; and

a projection system (e.g. a refractive projection lens system) PS configured to project a pattern imparted to the radiation beam B by patterning device MA onto a target portion C (e.g. comprising one or more dies) of the substrate W.

The illumination system may include various types of optical components, such as refractive, reflective, magnetic, electromagnetic, electrostatic or other types of optical components, or any combination thereof, for directing, shaping, or controlling radiation.

The support structure supports, i.e. bears the weight of, the patterning device. It holds the patterning device in a manner that depends on the orientation of the patterning device, the design of the lithographic apparatus, and other conditions, such as, for example, whether or not the patterning device is held in a vacuum environment. The support structure may use mechanical, vacuum, electrostatic or other clamping techniques to hold the patterning device. The support structure may be a frame or a table, for example, which may be fixed or movable as required. The support structure may ensure that the patterning device is at a desired position, for example, with respect to the projection system. Any use of the terms “reticle” or “mask” herein may be considered synonymous with the more general term “patterning device.”

The term “patterning device” used herein should be broadly interpreted as referring to any device that may be used to impart a radiation beam with a pattern in its cross-section such as to create a pattern in a target portion of the substrate. It should be noted that the pattern imparted to the radiation beam may not exactly correspond to the desired pattern in the target portion of the substrate, for example, if the pattern includes phase-shifting features or so called assist features. Generally, the pattern imparted to the radiation beam will correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which may be individually tilted so as to reflect an incoming radiation beam in different directions. The tilted mirrors impart a pattern in a radiation beam which may be reflected by the mirror matrix.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

As here depicted, the apparatus is of a transmissive type (e.g. employing a transmissive mask). Alternatively, the apparatus may be of a reflective type (e.g. employing a programmable mirror array or employing a reflective mask).

The lithographic apparatus may be of a type having two (dual stage) or more substrate tables (and/or two or more mask tables). In such “multiple stage” machines the additional tables may be used in parallel, or preparatory steps may be carried out on one or more tables while one or more other tables are being used for exposure.

The lithographic apparatus may also be of a type wherein at least a portion of the substrate may be covered by a liquid having a relatively high refractive index, e.g. water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems. The term “immersion” as used herein is not intended to suggest that a structure, such as a substrate, must be submerged in liquid, but rather means that liquid may be located between the projection system and the substrate during exposure.

Referring to FIG. 1, the illuminator IL receives a radiation beam from a radiation source SO. The source and the lithographic apparatus may be separate entities, for example, when the source is an excimer laser. In such cases, the source may not be considered to form part of the lithographic apparatus and the radiation beam is passed from the source SO to the illuminator IL with the aid of a beam delivery system BD that includes, for example, suitable directing mirrors and/or a beam expander. In other cases, the source may be an integral part of the lithographic apparatus, for example, when the source is a mercury lamp. The source SO and the illuminator IL, together with the beam delivery system BD, if used, may be referred to as a radiation system.

The illuminator IL may include an adjuster AD for adjusting the angular intensity distribution of the radiation beam. Generally, at least the outer and/or inner radial extent (commonly referred to as σ-outer and σ-inner, respectively) of the intensity distribution in a pupil plane of the illuminator may be adjusted. In addition, the illuminator IL may include various other components, such as an integrator IN and a condenser CO. The illuminator may be used to condition the radiation beam, to have a desired uniformity and intensity distribution in its cross-section.

The radiation beam B may be incident on the patterning device (e.g., mask MA), which may be held on the support structure (e.g., mask table MT), and may be patterned by the patterning device. Having traversed the mask MA, the radiation beam B may pass through the projection system PS, which focuses the beam onto a target portion C of the substrate W. With the aid of the second positioner PW and position sensor IF (e.g. an interferometric device, linear encoder or capacitive sensor), the substrate table WT may be moved accurately, e.g. so as to position different target portions C in the path of the radiation beam B. Similarly, the first positioner PM and another position sensor (which is not explicitly depicted in FIG. 1) may be used to accurately position the mask MA with respect to the path of the radiation beam B, e.g. after mechanical retrieval from a mask library, or during a scan. In general, movement of the mask table MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner) the mask table MT may be connected to a short-stroke actuator only, or may be fixed. Mask MA and substrate W may be aligned using mask alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the mask MA, the mask alignment marks may be located between the dies.

The depicted apparatus could be used in at least one of the following modes:

1. In step mode, the mask table MT and the substrate table WT may be kept essentially stationary, while an entire pattern imparted to the radiation beam is projected onto a target portion C. at one time (i.e. a single static exposure). The substrate table WT may then be shifted in the X and/or Y direction so that a different target portion C may be exposed. In step mode, the maximum size of the exposure field may limit the size of the target portion C imaged in a single static exposure.

2. In scan mode, the mask table MT and the substrate table WT may be scanned synchronously while a pattern imparted to the radiation beam is projected onto a target portion C (i.e. a single dynamic exposure). The velocity and direction of the substrate table WT relative to the mask table MT may be determined by the (de-)magnification and image reversal characteristics of the projection system PS. In scan mode, the maximum size of the exposure field may limit the width (in the non-scanning direction) of the target portion in a single dynamic exposure, whereas the length of the scanning motion may determine the height (in the scanning direction) of the target portion.

3. In another mode, the mask table MT may be kept essentially stationary holding a programmable patterning device, and the substrate table WT may be moved or scanned while a pattern imparted to the radiation beam is projected onto a target portion C. In this mode, generally a pulsed radiation source is employed and the programmable patterning device is updated, as required, after each movement of the substrate table WT or in between successive radiation pulses during a scan. This mode of operation may be readily applied to maskless lithography that utilizes programmable patterning device, such as a programmable mirror array of a type as referred to above.

Combinations and/or variations on the above described modes of use or entirely different modes of use may also be employed.

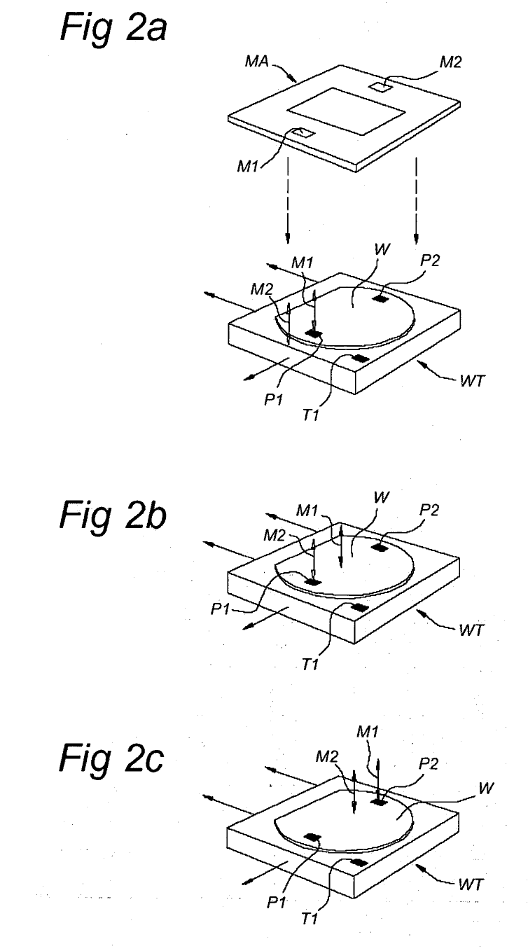

FIGS. 2a-c schematically show a known alignment arrangement in a lithographic apparatus. The mask MA may be provided with alignment marks M1 and M2, the substrate W may include alignment marks P1 and P2, while the substrate table WT may be provided with an alignment mark T1. First, the position sensor IF, shown in FIG. 1, may be calibrated by aligning the substrate table mark T1 to mask marks M1, M2 in the mask MA (not shown). Then, a complete alignment process may be carried out by aligning substrate mark P1 to mask marks M1 and M2 (FIGS. 2a-b) and substrate mark P2 to mask mark M1 (FIG. 2c). The actions shown in FIGS. 2a-b enable a determination of the mask rotation and lens magnification. The substrate W and mask MA may be consecutively fully aligned by aligning substrate mark P1 to mask mark M1, substrate mark P2 to mask mark M1, and then aligning substrate mark P1 to mask mark M1 and substrate mark P1 to mask mark M2 (all these actions are not shown). After these alignments, the substrate W may be exposed.

Generally, a number of process layers are formed on top of substrate W, in which each process layer may include device patterns. The patterns in consecutive process layers should be aligned with respect to each other. Therefore, before each exposure, the position of the other device patterns in earlier process layers should be known. In one embodiment of the invention, this may be done by local etching of the process layers to reveal the zero-layer marks P1₀ and P2₀ (FIG. 2c), which may be the marks placed in the earliest “zero”-layer of the substrate. Together with the available marks in the n-th process layer, these marks may be used in the alignment procedure explained earlier. The marks typically have a cross-sectional area of 400 μm squared, while the area that is etched away typically has a cross-sectional area of 1200 μm squared.

A substrate W, which is formed by bonding a first substrate having a device pattern and a second substrate without a device pattern may be aligned in the same way as described above. In one embodiment in the second substrate, holes may be etched that are sufficiently large that alignment marks in the first substrate may be detected through such holes. However, etching through an entire substrate takes a lot of time and effort and therefore may be expensive. To reduce costs, the currently used second substrates in such a substrate W may have a thickness that does not exceed 100 μm. However, a number of applications include a second substrate with a “normal” thickness, i.e. about 650 μm, in which holes can hardly be etched within a reasonable period of time.

The present invention enables the use of a second substrate having a more normal thickness to create a bonded substrate W with a first substrate by adapting the bonded substrate in an earlier stage. As a result, the etching step in the normal procedure may be avoided.

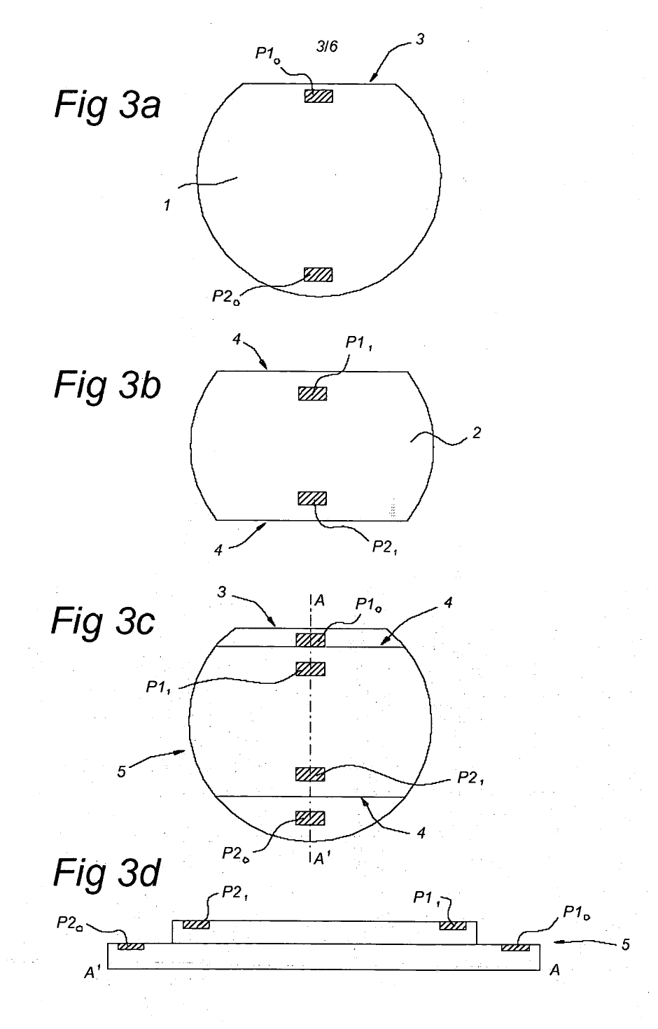

FIG. 3a shows a top view of a first substrate 1 that includes one or more devices and that also includes alignment marks P1₀ and P2₀. The first substrate 1 may include a single orientational flat 3, commonly referred to as “flat”. A flat is a linear part in a substantially circular circumference of a substrate that defines a corner of the substrate, which may identify its pattern surface and its rotational orientation. FIG. 3b shows a top view of a second substrate 2, preferably without a device pattern, that may be provided with alignment marks P1₁ and P2₁. The second substrate 2 has two flats 4, i.e. a flat 4 at two sides of the substrate 2. The first substrate 1 may have a longer flat diameter than the flat diameter of the second substrate 2, wherein the flat diameter is defined as the linear dimension across the surface of a substrate from the center of the flat through the substrate center to the circumference of the substrate on the opposite edge. Alignment marks P1₁ and P1₂ may be used to determine the position of the substrate surface facing away from the bonded interface in a direction perpendicular thereto. Furthermore, they may be used to improve alignment between consecutive layers (overlay) that are provided after bonding.

FIG. 3c shows a top view of a bonded structure 5 to be exposed in a lithographic apparatus according to a first embodiment of the present invention. The bonded structure 5 may be formed by bonding the first substrate 1, shown in FIG. 3a, to the second substrate 2, shown in FIG. 3b. Marks P1₀ and P2₀ of the first substrate 1 may be positioned at locations that are not covered by the second substrate 2 due to the presence of flats 4. An alignment procedure, as discussed with reference to FIG. 2, is therefore possible at all times. FIG. 3d shows a cross-sectional side view of the same bonded structure 5 along line A-A′ in FIG. 3c. Even when additional process layers are provided on top of the second substrate 2, marks P1₀ and P2₀ remain visible, and can therefore be used to align the bonded substrate 5 with respect to the mask MA with an alignment tool within the lithographic apparatus.

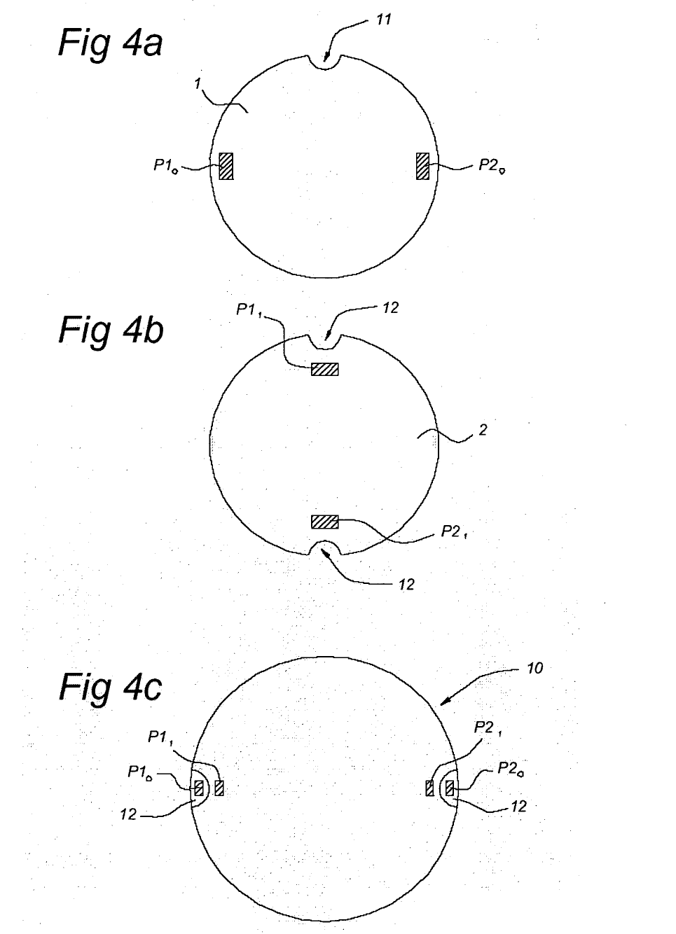

FIG. 4c shows a top view of a bonded structure 10 to be exposed in a lithographic apparatus according to a second embodiment of the present invention. The bonded structure 10 is again formed by a first substrate 1 provided with alignment marks P1₀ and P2₀ (FIG. 4a) and a second substrate 2 provided with alignment marks P1₁ and P2₁ (FIG. 4b). Instead of a flat 3, the first substrate 1 may include a single notch 11, i.e. a cut or the like on the edge of the substrate. In the case of the substrate being a wafer, the notch may be commonly located with respect to a specific crystal plane of the wafer. The second substrate 2 may have two notches 12, preferably positioned at opposing ends. In the shown embodiment, neither P1₀ or P2₀ are positioned near the notch 11. However, when there is enough space available, for instance because the notches 12 of the second substrate 2 having a larger diameter than the notch 11 of the first substrate 1, either one of mark P1₀ and P2₀ may be positioned in close vicinity of the notch 11. To form the bonded structure 10 shown in FIG. 4c, the second substrate 2 may be rotated over 90 degrees before bonding. Again, when both substrates 1, 2 are bonded, marks P1₀ and P2₀ may not be covered by the second substrate 2, and can therefore be used in an alignment procedure.

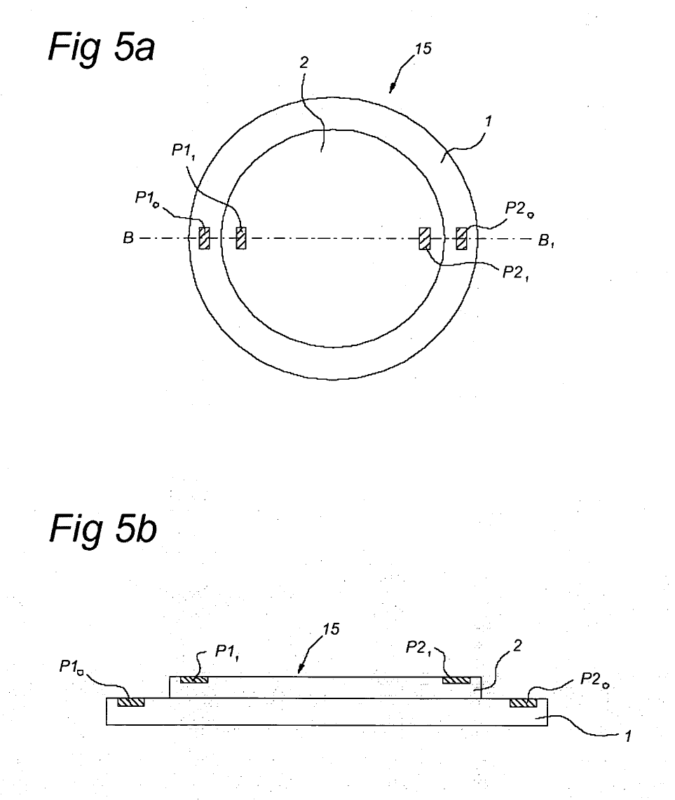

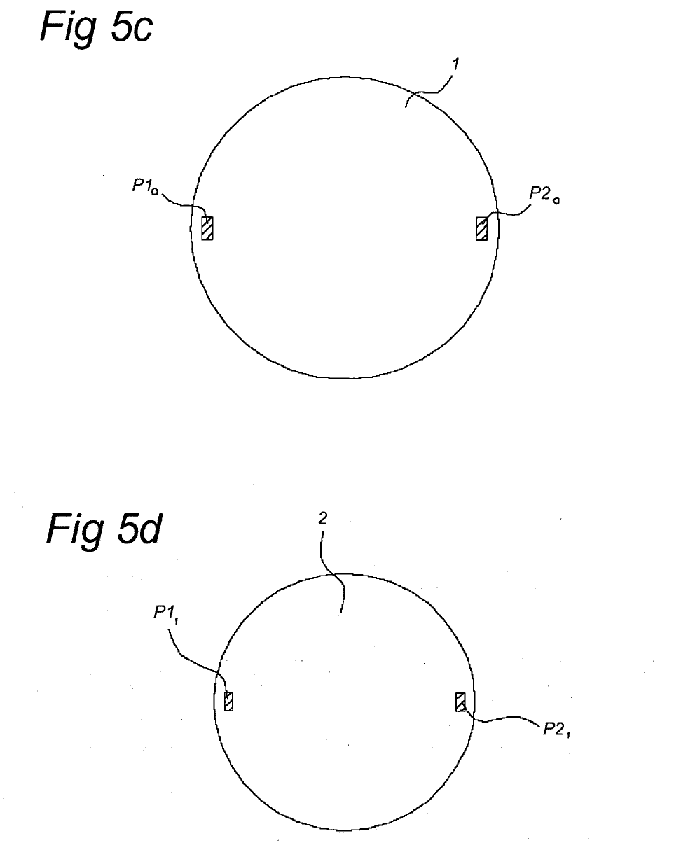

FIGS. 5a-b respectively show a top view and a cross-sectional side view along line B-B′ of a bonded structure 15 to be exposed in a lithographic apparatus according to a third embodiment of the present invention. The bonded structure 15 may again be formed by a first substrate 1 provided with alignment marks P1₀ and P2₀ (FIG. 5c) and a second substrate 2 provided with alignment marks P1₁ and P2₁ (FIG. 5d). The diameter of the first substrate 1 may be larger than the diameter of the second substrate 2. As a result, marks P1₀ and P2₀, that are located sufficiently far from the center of the first substrate 1, may remain visible after the bonding of the two substrates 1, 2.

It should be understood that the scope of the invention is not limited to the shown embodiments. Many combinations of the shown examples fall within the scope of the invention.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

Although specific reference may have been made above to the use of embodiments of the invention in the context of optical lithography, it will be appreciated that the invention may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

The terms “radiation” and “beam” used herein encompass all types of electromagnetic radiation, including ultraviolet (UV) radiation (e.g. having a wavelength of or about 365, 355, 248, 193, 157 or 126 nm) and extreme ultra-violet (EUV) radiation (e.g. having a wavelength in the range of 5-20 nm), as well as particle beams, such as ion beams or electron beams.

The term “lens”, where the context allows, may refer to any one or combination of various types of optical components, including refractive, reflective, magnetic, electromagnetic and electrostatic optical components.

While specific embodiments of the invention have been described above, it will be appreciated that the invention may be practiced otherwise than as described. For example, the invention may take the form of a computer program containing one or more sequences of machine-readable instructions describing a method as disclosed above, or a data storage medium (e.g. semiconductor memory, magnetic or optical disk) having such a computer program stored therein.

Other embodiments, uses and advantages of the invention will be apparent to those skilled in the art from consideration of the specification and practice of the invention disclosed herein. The specification should be considered exemplary only, and the scope of the invention is accordingly intended to be limited only by the following claims.

What is claimed is:

1. A method of forming a bonded substrate, comprising:
providing a first substrate having a first substrate shape and having at least one first alignment mark that is positioned at a first surface side;
providing a second substrate having a second substrate shape;
orienting said second substrate relative to said first substrate in a predetermined orientation; and
bonding said second substrate to said first surface side of said first substrate to provide a bonded substrate, such that said bonded second substrate does not cover said at least one first alignment mark.

2. The method according to claim 1, wherein said second substrate is provided with at least one second alignment mark positioned on a second surface side that is not bonded to said first surface side of said first substrate.

3. The method according to claim 1, wherein said second substrate includes at least one flat, wherein the flat is oriented to expose said at least one first alignment mark when the second substrate is bonded to the first substrate.

4. The method according to claim 1, wherein said second substrate includes at least one notch, wherein the notch is oriented to expose said at least one first alignment mark when the second substrate is bonded to the first substrate.

5. The method according to claim 1, wherein said first and second substrates have cross-sectional areas with a substantially circular shape, the first substrate having a first radius and the second substrate having a second radius, the first radius of the first substrate exceeding a length of the second radius of the second substrate, such that said at least one alignment mark is exposed when the second substrate is bonded to the first substrate.

6. The method according to claim 1, wherein said second substrate has a thickness larger than 100 μm.

7. A bonded substrate, comprising:
a first substrate having a first outer circumference and at least one first alignment mark that is positioned at a first surface side; and
a second substrate that is positioned on top of said first substrate, the second substrate having a second outer circumference, wherein said second outer circumference, when projected on said first surface side of said first substrate in a direction substantially perpendicular to the first surface side, is at least partly enclosed by said first outer circumference, such that said at least one first alignment mark is exposed.

8. The bonded substrate according to claim 7, wherein said second substrate is provided with at least one second alignment mark that is located on a second surface side that is opposite to a surface that is bonded to said first surface side of said first substrate.

9. The bonded substrate according to claim 7, wherein said second substrate includes at least one flat, such that said at least one first alignment mark is exposed when the second substrate is bonded to the first substrate.

10. The bonded substrate according to claim 7, wherein said second substrate includdes at least one notch, such that said at least one first alignment mark is exposed when the second substrate is bonded to the first substrate.

11. The bonded substrate according to claim 7, wherein said first and second substrates have cross-sectional areas with a substantially circular shape, the first substrate having a first radius and the second substrate having a second radius, the first radius of the first substrate exceeding a length of the second radius of the second substrate, such that said at least one alignment mark is exposed when the second substrate is bonded to the first substrate.

12. The bonded substrate according to claim 7, wherein said second substrate has a thickness larger than 100 μm.

13. A device manufacturing method, comprising:
providing a first substrate having a first substrate shape and having at least one first alignment mark that is positioned at a first surface side;
providing a second substrate having a second substrate shape;
orienting the second substrate relative to said first substrate in a predetermined orientation;
bonding the second substrate to the first surface side of the first substrate to provide a bonded substrate, wherein the second substrate does not cover the at least one first alignment mark when the second substrate is bonded to the first substrate;
providing a projection beam of radiation;
using a pattern to impart the projection beam with a patterned cross-section; and
projecting the patterned beam of radiation onto a target portion of the bonded substrate

14. The method according to claim 13, wherein said second substrate includes at least one flat, wherein the flat is oriented to expose said at least one first alignment mark when the second substrate is bonded to the first substrate.

15. The method according to claim 13, wherein said second substrate includes at least one notch, wherein the notch is oriented to expose said at least one first alignment mark when the second substrate is bonded to the first substrate.

16. The method according to claim 13, wherein said first and second substrates have cross-sectional areas with a substantially circular shape, the first substrate having a first radius and the second substrate having a second radius, the first radius of the first substrate exceeding a length of the second radius of the second substrate, such that said at least one alignment mark is exposed when the second substrate is bonded to the first substrate.

17. The method according to claim 13, wherein said second substrate has a thickness larger than 100 μm.
